(19) United States
(12) Patent Application Publication
(10) Pub. No.: US 2025/0112147 A1
(43) Pub. Date: Apr. 3, 2025

(54) MAGNETIC AND ELECTRIC STRUCTURES IN TECHNOLOGIES WITH THROUGH-SILICON VIAS AND FRONT- AND BACK-END METAL LAYERS

(71) Applicant: Intel Corporation, Santa Clara, CA (US)

(72) Inventors: Xi Li, Chandler, AZ (US); Chuanzhao Yu, Phoenix, AZ (US); Yazan Hejazin, Chandler, AZ (US); Marco Bresciani, Scottsdale, AZ (US); Hyun Yoon, Gilbert, AZ (US); Lichung Chang, Mesa, AZ (US)

(73) Assignee: Intel Corporation, Santa Clara, CA (US)

(21) Appl. No.: 18/375,306

(22) Filed: Sep. 29, 2023

(51) Int. Cl. H01L 23/522; H01L 23/48; H01L 27/06

(52) U.S. Cl. CPC H01L 23/5227; H01L 23/481; H01L 23/5225; H10D 88/00

(57) ABSTRACT

An integrated circuit device with front- and back-side metals may include coils in interconnect structures on one or both sides of a semiconductor substrate. The coil(s) may include vias extending through (and coupling wires on both sides of) the substrate. The coil(s) may include multiple turns or loops. The coil(s) may be on one side, and parallel to, the substrate. Coils may be orthogonal or parallel to each other. A resistor may have smaller resistor segments on both sides of the substrate coupled by through-substrate vias. A capacitor may utilize through-substrate vias as plates. Through-substrate vias may inhibit eddy currents in the substrate. A cage of wires and through-substrate vias may shield devices within the cage from interfering fields external to the cage.

### BACKGROUND

Some passive components, such as inductors and transformers, are essential magnetic structures in certain applications. These essential structures are laid out in a lateral plane and often have low quality (Q) factor and inductance values while occupying a substantial area. Furthermore, coupling between lateral coils (or other structures) can impair signal integrity and result in path loss.

New structures and methods are needed to minimize inter-coil coupling and to reduce the space required for essential structures, both while improving (or at least not affecting) their reactance value or Q-factor. New structures and methods are also needed to provide isolation (e.g., shielding) from magnetic structures within a device.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A and 1B illustrate cross-sectional profile views of a coil in an integrated circuit (IC) device, including through-substrate vias coupled to wires in dielectric sections above and below a semiconductor substrate, in accordance with some embodiments;

FIGS. 2A, 2B, and 2C illustrate isometric and plan views of an IC device with various configurations of coils and turns through a substrate, in accordance with some embodiments;

FIG. 3 illustrates an isometric view of orthogonal coils through a substrate and in both front- and back-side dielectric sections, in accordance with some embodiments;

FIGS. 4A and 4B illustrate isometric views of an IC device with multiple coils in and through front and back sides, in accordance with some embodiments;

FIGS. 5A, 5B, 5C, and 5D illustrate isometric views of a substrate with an array of floating vias deployed in a region adjacent coils, in accordance with some embodiments;

FIGS. 6A and 6B illustrate cross-sectional profile views of a resistor utilizing through-substrate vias (TSV) and resistors on both sides of a substrate, in accordance with some embodiments;

FIGS. 7A, 7B, 7C, 7D, and 7E illustrate cross-sectional profile and plan views of a capacitor utilizing TSV between sides of substrate, in accordance with some embodiments;

FIGS. 8A, 8B, 8C, and 8D illustrate isometric, cross-sectional profile, and plan views of an isolation or Faraday cage in an IC device, in accordance with some embodiments;

FIG. 9 is a flow chart of methods for forming magnetic and/or electric structures in an IC device with front- and back-side interconnect structures, in accordance with some embodiments;

FIG. 10 illustrates a diagram of an example data server machine employing an IC device having front- and back-side interconnects and utilizing TSV in magnetic and/or electric structures, in accordance with some embodiments; and

FIG. 11 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x-z and y-z planes, and plan views are taken in the x-y plane. Typically, profile views in the x-z plane are cross-sectional views. Where appropriate, drawings are labeled with axes to indicate the orientation of the figure.

Structures and techniques are disclosed to improve the performance of integrated circuit (IC) devices with front- and back-side interconnects using through-substrate vias (TSV). With magnetic coils limited to deployment on a horizontal surface of a semiconducting substrate, it is difficult to minimize coupling between these coils, as their magnetic fluxes will be parallel to each other and perpendicular to the surface. Horizontal, planar coils also occupy large areas of the substrate surface, but are limited to single turns (e.g., in the single, surface plane), which limits their maximum inductances. Horizontal, planar coils may also be limited to relatively thin metallization layers, which may increase coil resistivity and limit inductor quality (Q) factor. Using TSV in coils enables the use of thicker metal structures (e.g., metal interconnects in upper layers of front- and back-side interconnects), which enables increased Q factors. Using TSV in coils also enables the coils to be oriented orthogonally to the substrate, which provides layout flexibility (e.g., to avoid coupling between these coils) and allows for occupied area to be reduced. Coils can use vertical space, rather than valuable and more-limited lateral area. TSV and orthogonally oriented coils also enables the deployment of multiple turns within an inductor coil. Coils can be placed in all three orthogonal planes to maximize de-confliction of magnetic coupling between coils. Floating TSV can be deployed in extensive arrays to minimize eddy currents induced by coils parallel to the substrate.

TSV can also be used to save area in resistors and capacitors. TSV can be used to couple resistors on both sides of the substrate, which together form resistors (or resistor networks) with increased resistance efficiency (relative to occupied area) and layout flexibility. TSV can be used as parallel plates in a capacitor spanning the substrate, which again uses the z direction to save lateral area in the IC device.

TSV can also be used to enclose components or particular portions in a grounded, isolation cage, which may shield those components or portions from electromagnetic fields (e.g., from the coil(s)).

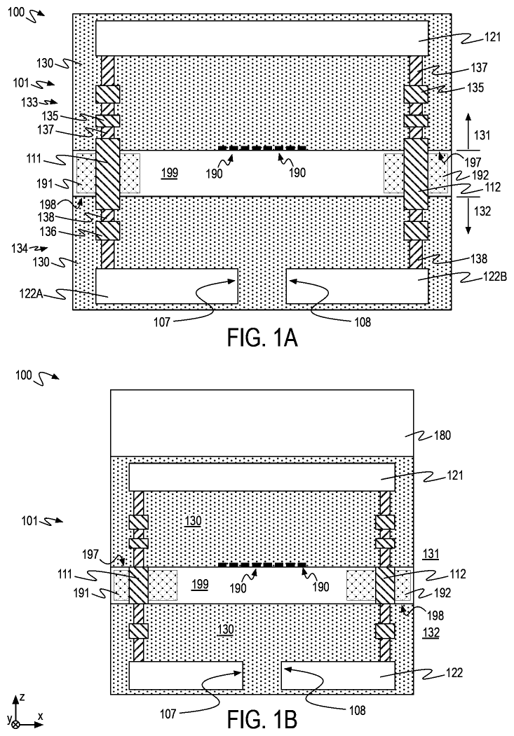

FIGS. 1A and 1B illustrate cross-sectional profile views of a coil 101 in an IC device 100, including through-substrate vias 111, 112 coupled to wires 121, 122 in dielectric sections 130 above and below a semiconductor substrate 199, in accordance with some embodiments. FIG. 1A shows an apparatus or device 100, including coil 101, which has multiple electrically conductive portions in series connection between terminals 107, 108. Device 100 includes substrate 199 of a semiconductor material between dielectric sections 130 on upper and lower sides 131, 132 of substrate 199. In some embodiments, upper side 131 is a front side of substrate 199, and lower side 132 is a back side of substrate 199. In some such embodiments, at least some metals (e.g., interconnects) on a back side 132 provide power delivery and are generally thicker (e.g., have larger diameters) than metals (e.g., interconnects) on a front side 131. Upper surface 197 is on upper side 131, and lower surface 198 is on lower side 132. Other orientations or configurations may be employed. Although upper and lower sides 131, 132 may be front or back sides in at least some examples described herein, such references are not limiting. Front or back sides need not correspond to front- or back-end operations. For example, the orientation of coil 101 or components of coil 101 (or other portions of device 100) need not depend on a build-up direction from substrate 199 or any other manufacturing process.

IC device 100 includes coil 101. Coil 101 includes vias 111, 112. Vias 111, 112 are through-substrate vias (TSV) and extend in the z direction, perpendicular to and through substrate 199, which may have a shorter thickness in the z direction than length or width in the x and y directions. TSV 111, 112 extend between upper and lower dielectric sections 130. Via 111 is through a first region 191 of substrate 199. Via 112 is through a second region 192 of substrate 199. A large group or array of transistor structures 190 is on substrate 199 and between regions 191, 192 and between upper and lower dielectric sections 130.

Vias, including in TSV 111, 112, are used herein to refer to generally vertical conductors between different levels or heights or layers of device 100. For example, TSV 111, 112 may be of copper or another metal, and vias 111, 112 extend or span between surfaces 197, 198 on sides 131, 132 of substrate 199. Vias 111, 112 may be of any suitable material or materials, e.g., multiple metals. In some embodiments, vias 111, 112 include a liner metal or material (such as tungsten, etc.) around a fill metal (e.g., of copper, cobalt, etc.). Other structures and materials may be used.

Vias 111, 112 may be substantially cylindrical in shape (e.g., having a circular cross-section) or other shapes. Whether cylindrical or otherwise shaped, vias 111, 112 (or some portions of vias 111, 112) may have a slightly tapered aspect, having a somewhat narrower cross-section at one end. Vias 111, 112 may have substantially rectilinear cross-sections, for example, square cross-sections. In many embodiments, vias 111, 112 have substantially or somewhat rectilinear cross-sections, but with rounded corners. Vias 111, 112 may have cross-sections with other shapes.

TSV 111, 112 may be encircled or encased laterally by a layer of insulating material, which may insulate (e.g., electrically isolate) TSV 111, 112 from a semiconducting material of substrate 199. The layer of insulating material may be a dielectric material. In many embodiments, substrate 199 is a silicon substrate, and TSV 111, 112 are insulated from substrate 199 by a silicon oxide (e.g., SiO₂) encircling each vias 111, 112.

Vias 111, 112 are alike, the same except that the different reference numbers may indicate the side (e.g., in either x direction) of coil 101 that vias 111, 112 are on. Vias 111 extend through regions 191, and vias 112 extend through regions 192. Substrate 199 includes a group of transistor structures 190 on upper surface 197, and transistor structures 190 are between regions 191, 192 of substrate 199. In some embodiments, regions 191, 192 each occupy an outer 20% of the cross-sectional width of substrate 199 (e.g., in the x direction). In some embodiments, regions 191, 192 each occupy an outer 10% of the width of substrate 199, which may correspond to an increased cross-sectional area of coil 101 and consequently higher inductance. In some embodiments, regions 191, 192 each occupy an outer 5% of the width of substrate 199, which may correspond to a yet higher cross-sectional area and inductance of coil 101.

Coil 101 includes wire 121 in upper dielectric section 130 on front side 131 of substrate 199. Wire 121 extends in the x direction, perpendicular to vias 111, 112 and the z direction and parallel to substrate 199. Wire 121 couples vias 111, 112. Coil 101 includes wires 122A, 122B in lower dielectric section 130 on a back side 132 of substrate 199. Wires 122A, 122B extend in the x direction. Via 111 couples wires 121, 122A. Via 112 couples wires 121, 122B. Wires are used herein to refer to lateral conductors, including wires 121, 122, in dielectric sections 130. Dielectric sections 130 may be of any suitable material or materials that electrically insulates circuit components separated by the material(s), such as oxides (e.g., SiO₂), nitrides (including oxynitrides), etc., of silicon. For example, wire 121 of coil 101 may be insulated from other wires by silicon dioxide in dielectric section 130 on side 131.

Interconnect structures 133, 134 are on sides 131, 132, respectively, within dielectric sections 130. Interconnect structures 133, 134 include wires (including wires 121, 122) and vias routing through the insulating material(s) of dielectric sections 130. Wires 121, 122 may be typical of lateral interconnects in interconnect structures in front and back sides of IC devices. Wires 121, 122 may have typical structures (e.g., of bars or trenches through dielectric materials) and be of typical materials (e.g., copper fill within liner metals, etc.).

In the example of FIG. 1A, coil 101 incudes interconnect conductors 135, 136, 137, 138 in interconnect structures 133, 134. As shown in FIG. 1A, vias 111, 112 may couples wires 121, 122 by or through interconnect structures 133, 134 in dielectric sections 130 on sides 131, 132, respectively. Interconnect conductors 135, 136 may be within discrete metallization layers in interconnect structures 133, 134 in dielectric sections 130 on sides 131, 132, respectively. Interconnect conductors 137, 138 may be vias between discrete metallization layers in interconnect structures 133, 134 in dielectric sections 130 on sides 131, 132, respectively. Interconnect conductors 135, 137 are parts of interconnect structure 133, and via 111 is coupled to wire 121 by interconnect conductors 135, 137 in dielectric section 130 on side 131. Interconnect conductors 136, 138 are parts of interconnect structure 134, and via 111 is coupled to wire 122A by interconnect conductors 136, 138 in dielectric section 130 on side 132. Via 112 is coupled to wire 121 by interconnect conductors 135, 137 in dielectric section 130 on side 131. Via 112 is coupled to wire 122B by interconnect conductors 136, 138 in dielectric section 130 on side 132. Coil 101 may utilize wires 121, 122 in any desired layer of interconnect structures 133, 134 and so any desired size within interconnect structures 133, 134, which enables the deployment of coil 101 with desired characteristics (such as inductance value).

Coil 101 has terminals 107, 108, which may be coupled to other components or circuits, e.g., within device 100. In some embodiments, one or more TSV couple coil 101 (e.g., at one or both of terminals 107, 108) to components or circuits on upper side 131. In some embodiments, one or more interconnect conductors 136, 138 couple coil 101 (e.g., at one or both of terminals 107, 108) to components or circuits on lower side 132.

Coil 101 is oriented on an x-z plane, orthogonal to the y direction. Vias 111, 112 and wires 121, 122 are oriented and configured such that the currents flowing through these (and other) portions of coil 101 generate magnetic fluxes that are additive or reinforcing within coil 101. Current flowing through coil 101, depending on the direction of the current between terminals 107, 108, will generate a magnetic flux flowing through coil 101 in the positive or negative y direction and looping back around the outside of coil 101 in the negative or positive y direction. Coils are used herein to refer to inductors having series-connected conductive (e.g., metal) elements bounding at least three sides of a coil cross-sectional area. Coil 101 may be used in digital applications (e.g., with millions of small transistor structures 190), analog applications (e.g., with fewer, larger transistor structures 190), and/or mixed or combined or other applications. For example, coil 101 may be part of a power regulation circuit (e.g., a boost-buck circuit), a signal filter, etc.

Substrate 199 may include any suitable material or materials. Any suitable semiconductor or other material can be used. Substrate 199 may be any suitable substrate, such as a wafer, die, etc. Substrate 199 may include a semiconductor material that transistors can be formed out of and on, including a crystalline material, such as monocrystalline or polycrystalline silicon (Si), germanium (Ge), silicon germanium (SiGe), a III-V alloy material (e.g., gallium arsenide (GaAs)), a silicon carbide (SiC), or any combination thereof. In some embodiments, substrate 199 includes crystalline silicon and subsequent components are also silicon. Substrate 199 may be a silicon-on-insulator (SOI) substrate. Substrate 199 may include sapphire (Al₂O₃). One or more fins of semiconductor material may be included in or on substrate 199. The fin or fins may be of the same material as substrate 199 or formed, e.g., deposited, on substrate 199. Substrate 199 may also include semiconductor materials, metals, dielectrics, dopants, and other materials commonly found in IC substrates.

Substrate 199 may be very thin, e.g., much thinner than standard starting IC wafers or dies. For example, substrate 199 may be less than 100 μm thick. In some embodiments, substrate 199 has a thickness of 50 μm or less. A thinner substrate 199 corresponds to shorter TSV, which may allow for less series resistances, e.g., for TSV 111, 112 in coil 101. Less resistive conductors in coil 101 enables higher quality factors (Q) for coil 101.

FIG. 1B illustrates IC device with carrier 180 over dielectric section 130 on side 131. Carrier 180 may be much thicker (e.g., have a greater height in the z direction) than substrate 199 and/or dielectric sections 130. Carrier 180 may provide mechanical strength to device 100, including during processing of device 100, which may include thinning (e.g., by back grinding, polishing, etc.) of substrate 199. Carrier 180 may be an amorphous (e.g., glass) or crystalline material, or any other suitable material. Carrier 180 may be doped to improve one or more of various properties, including resistivity or thermal conductance.

Carrier 180 may be coupled to dielectric section 130 on side 131 by any suitable means, for example, direct bonding. In some embodiments, device 100 includes an interface layer, e.g., for bonding (or facilitating a bond between) carrier 180 and dielectric section 130 on side 131. In some embodiments, carrier 180 includes metallization structures, e.g., for bonding to dielectric section 130.

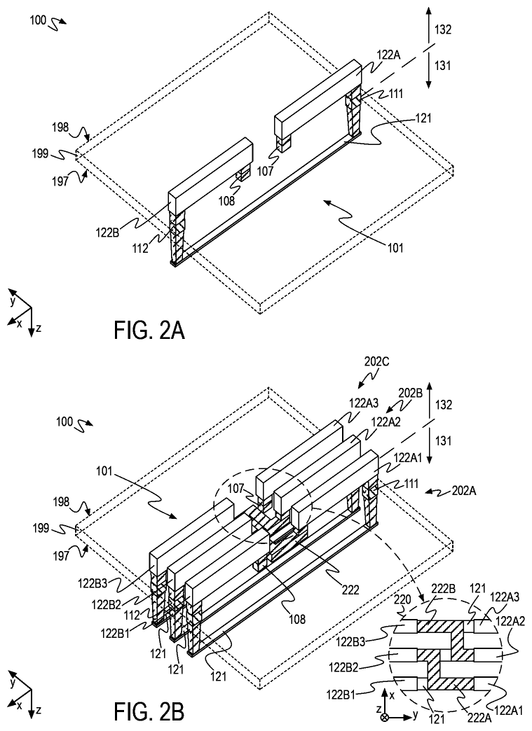

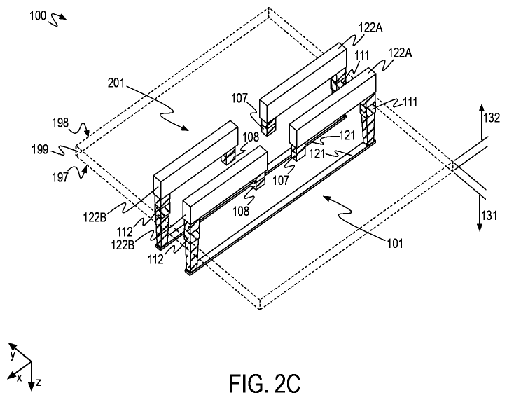

FIGS. 2A, 2B, and 2C illustrate isometric and plan views of IC device 100 with various configurations of coils 101, 201 and turns 202 through substrate 199, in accordance with some embodiments. FIGS. 2A and 2B show isometric perspectives from below lower side 132. Lower side 132 is shown above upper side 131. FIG. 2A illustrates coil 101 oriented similarly to coil 101 shown in FIG. 1A or 1B, but for clarity or illustrative purposes, without dielectric sections 130, etc. For example, wire 121 (in upper dielectric section 130, not shown) is shown beyond (e.g., in the positive z direction) wires 122A, 122B (which are in lower dielectric section 130, not shown). The edges of substrate 199 are shown as dashed lines, but the locations of TSV 111, 112 (which are through substrate 199) also indicate the location of substrate 199. In the example of FIG. 2A, front side wire 121 has a smaller cross-sectional area than thicker back side wires 122A, 122B.

FIG. 2B shows coil 101 with multiple turns 202. Turns 202 are coupled by interconnection wires 222. For example, loop or turn 202A is coupled to turn 202B, and turn 202B is coupled to turn 202C, by separate interconnection wires 222. Interconnection wires 222 are in lower dielectric section on side 132. Each interconnection wire 222 has a portion extending in the x direction and portions extending in the y direction. Interconnection wires 222 are shown in the isometric view, as well as the inset plan view 220 of FIG. 2B.

Plan view 220 shows couplings between turns 202, where wires 222 (e.g., wires 222A, 222B) couple between wires 122A (e.g., wires 122A1, 122A2, 122A3), 122B (e.g., wires 122B1, 122B2, 122B3) in different turns 202. For example, wire 222A couples wire 122A1 in turn 202A to wire 122B2 in turn 202B, and wire 222B couples wire 122A2 in turn 202B to wire 122B3 in turn 202C. Wires 121 on upper side 131 are behind wires 122 on lower side 132. For example, wire 121 in turn 202C is behind (and can be seen between) wire 122A3 in turn 202C and wire 222B. Wire 121 in turn 202A is behind (and can be seen between) wire 122B1 in turn 202A and wire 222A. Wire 121 in turn 202B is behind (and can be seen between) wires 222A, 222B.

Coil 101 has terminals 107, 108, which are coupled by the multiple loops or turns 202. In each of turns 202A, 202B, 202C (as in the cases of coils 101 in FIGS. 1A-2A), via 111 couples wires 121, 122A; wire 121 on upper side 131 couples vias 111, 112; and via 112 couples wires 121, 122B. In the example of FIG. 2B, coil 101 has other, additional couplings. Interconnection wire 222 couples wire 122A in one turn to wire 122B in the next turn. Each of wires 122A, 122B, 222 on lower side 132 couple via 111 in in one turn to via 112 in the next turn. For example, wire 122A1 couples via 111 in turn 202A to via 112 in turn 202B (as do wires 122B2, 222A). Coil 101 continues in second turn 202B, where via 112 in turn 202B couples wires 122B2 and (in turn 202B) wire 121, and third turn 202C. These couplings are mechanical, as well as electrical. The electrical couplings are series connections, such that the current entering a component exits the same component. (Parallel connections and branches may also be utilized.)

In addition to being electrically coupled, turns 202 are magnetically coupled. As described at least at FIG. 1A, vias 111, 112 and wires 121, 122 are oriented and configured such that the currents flowing through these (and other) portions of coil 101 generate magnetic fluxes that are additive or reinforcing within coil 101. Additionally, these vias 111, 112 and wires 121, 122 in each turn 202 reinforce the magnetic fluxes generated in other turns 202. This reinforcement increases the magnetic flux flowing through coil 101 in the positive or negative y direction, which loops back around the outside of coil 101 in the opposite (e.g., negative or positive) y direction.

FIG. 2C shows adjacent, (mechanically or geometrically) parallel, magnetically coupled coils 101, 201. Coils 101, 201 may be series connected (e.g., by an interconnection wire 222) to be turns in a single coil (much as described at FIG. 2B), but coils 101, 201 may be electrically connected otherwise. In some embodiments, coils 101, 201 are deployed in a differential pair (e.g., coupled at terminals 108).

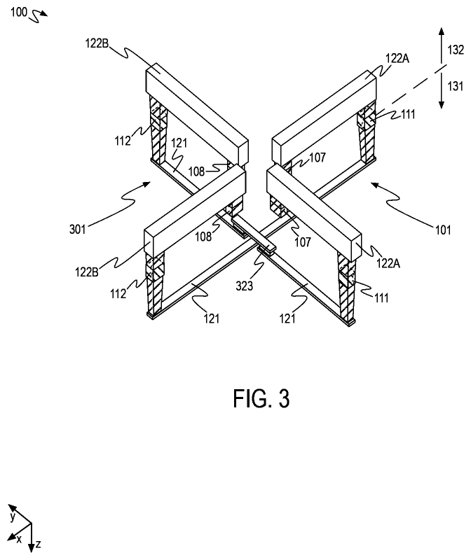

FIG. 3 illustrates an isometric view of orthogonal coils 101, 301 through substrate 199 and in both front- and back-side 131, 132 dielectric sections, in accordance with some embodiments. Although, e.g., for illustrative clarity, the dielectric sections and substrate are not shown, the substrate location is indicated by vias 111, 112, which are TSV 111, 112. Additionally, substrate orientation is indicated by wires 121 (shown behind other components) being in an upper, front side 131 of the substrate and wires 122 (shown in the foreground) in a lower, back side 132 of the substrate.

Coil 101 is much as previously described (e.g., at least at FIGS. 1A and 2A), and coil 301 is similar, but oriented orthogonally to coil 101 in a magnetically uncoupled configuration. Coil 301 also includes TSV 111, 112 (extending through the substrate and between the first and second dielectric sections in the z direction) and wires 121, 122. In coil 301, wires 121, 122 are again in upper and lower dielectric sections on front and back sides 131, 132, respectively. Notably, in coil 301, wires 121, 122 extend in a direction parallel to the substrate (e.g., in the y direction), but perpendicular to the x direction of wires 121, 122 in coil 101 (as well as perpendicular to the z direction of TSV 111, 112 in both coils 101, 301). Coil 301 is oriented on a y-z plane, orthogonal to the x direction. As in coil 101, TSV 111, 112 and wires 121, 122 in coil 301 are oriented and configured such that the currents flowing through these (and other) portions of coil 301 generate magnetic fluxes that are additive or reinforcing within coil 301. Current flowing through coil 301, depending on the direction between terminals 107, 108, will generate a magnetic flux flowing through coil 301 in the positive or negative x direction and looping back around the outside of coil 301 in the negative or positive x direction. The relative (e.g., orthogonal) orientations of coils 101, 301 has the effect of preventing (or minimizing) magnetic coupling between coils 101, 301, and thereby preventing (or minimizing) interference between coils 101, 301.

In some embodiments, wires 121 of coils 101, 301 are in a same layer (e.g., in an interconnect structure in an upper dielectric section on front side 131), and bridge wire 323 couples wires 121 in coil 301 and enables the crossing of wires 121 of coils 101, 301. In some other embodiments, wires 121 in separate coils 101, 301 are in different layers in an interconnect structure in a same-side dielectric section. In still other embodiments, other routings are used. For example, a wire 121 (or 122) in one of coils 101, 301 may cross through a gap between wires 122 (or 121) in the other of coils 101, 301 (e.g., between a pair of terminals 107, 108). In some embodiments, a wire 121 without a bridge wire 323 routing around (e.g., over or under) another wire 121 includes a similar structure, which matches that of an adjacent coil, e.g., to provide a same or similar behavior or performance to that of the adjacent coil.

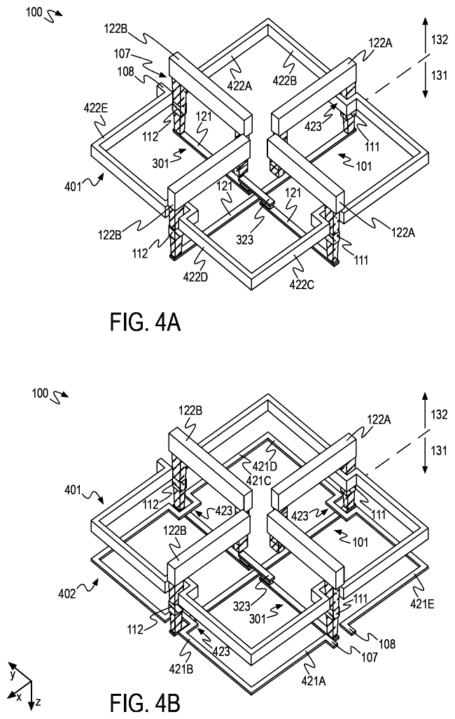

FIGS. 4A and 4B illustrate isometric views of IC device 100 with multiple coils 101, 301, 401, 402 in and through front and back sides 131, 132, in accordance with some embodiments. Device 100 includes the substrate and dielectric sections, which are not shown, e.g., for illustrative clarity, but which are as previously described. For example, the substrate may include one or more transistors on an upper side 131 of the substrate. Wires 121, 122 are in dielectric sections (not shown) on either side 131, 132 of the semiconductor substrate (not shown). The location of certain components, e.g., coil 401, relative to the substrate can be determined by positions relative to TSV 111, 112, which are through the substrate. For example, coil 401 is on side 132, between wires 122 and TSV 111, 112 (and the substrate TSV 111, 112 are through).

FIG. 4A shows coil 401 on back side 132. Coil 401 may be coupled (e.g., at terminals 107, 108) by TSV (not shown) to circuits, components (e.g., transistors), etc. (e.g., not shown), on front side 131. (Terminal 107 is obscured in FIG. 4A by coil 301.) Coil 401 may be coupled by interconnect conductors, also on back side 132, to other circuits, components (e.g., transistor structures 190), etc.

Coil 401 is in back side 132 dielectric section. Coil 401 includes wires 422. Wires 422A, 422B, 422C, 422D, 422E are series connected and (individually and collectively) couple terminals 107, 108. Wires 422B, 422C, 422D each include (or are internally coupled by) routing wires 423, which route wires 421 around vias 111, 112. Wires 422 are parallel to the substrate (not shown). Wires 422A, 422E are parallel to wire(s) 422C. Wires 422B, 422D are parallel. Wires 422B, 422D are perpendicular to wires 422A, 422C, 422E. Wires 422B, 422D are coupled by 422C. Wires 422C, 422E are coupled by 422D. Wires 422A, 422C are coupled by 422B.

Coil 401 is oriented on an x-y plane, orthogonal to the z direction. As in coils 101, 301, wires 422 in coil 401 are oriented and configured such that the currents flowing through these (and other) portions of coil 401 generate magnetic fluxes that are additive or reinforcing within coil 401. Current flowing through coil 401, depending on the direction between terminals 107, 108, will generate a magnetic flux flowing through coil 401 in the positive or negative z direction and looping back around the outside of coil 401 in the negative or positive z direction. The relative (e.g., orthogonal) orientations of coils 101, 301, 401 has the effect of preventing (or minimizing) magnetic coupling between coils 101, 301, 401, and thereby preventing (or minimizing) interference between coils 101, 301, 401.

FIG. 4B shows device 100 with an additional coil 402 oriented similarly to coil 401, but on front side 131. Coil 402 may be coupled (e.g., at terminals 107, 108) by TSV (not shown) to circuits, components (e.g., transistors), etc. (e.g., not shown), on back side 132. Coil 402 may be coupled by interconnect conductors, also on front side 131, to other circuits, components, etc. Coil 402 is in front side 131 dielectric section. As implied by the locations of TSV 111, 112, the substrate (not shown) is between coils 401, 402 and between front- and back-side 131, 132 dielectric sections. The substrate may be as previously described and may include, for example, transistors on side 131 of the substrate.

Device 100 may have one, all, or any combination of coils 101, 301, 401, 402, as described herein, as well as in other combinations. In some embodiments, coil 401 (with or without other coils 101, 301, 401, 402) is on side 132 of a semiconductor substrate, opposite a group of transistors on side 131 of the substrate. In some embodiments, coils 401, 402 are deployed together in or as a differential pair configuration.

Coil 402 includes wires 421. Wires 421A, 421B, 421C, 421D, 421E are series connected and (individually and collectively) couple terminals 107, 108. Wires 421B, 421C, 421D each include (or are internally coupled by) routing wires 423, which route wires 421 around vias 111, 112. Wires 421 are parallel to the substrate (not shown). Wires 421A, 421E are parallel to wire(s) 421C. Wires 421B, 421D are parallel. Wires 421B, 421D are perpendicular to wires 421A, 421C, 421E. Wires 421B, 421D are coupled by 421C. Wires 421C, 421E are coupled by 421D. Wires 421A, 421C are coupled by 421B.

Like parallel coil 401, coil 402 is orthogonal to coils 101, 301, so coil 402 may be substantially uncoupled with coils 101, 301 magnetically. Coil 402 is oriented on an x-y plane, orthogonal to the z direction. As in coils 101, 301, 401, wires 421 in coil 402 are oriented and configured such that the currents flowing through these (and other) portions of coil 402 generate magnetic fluxes that are additive or reinforcing within coil 402. Current flowing through coil 402, depending on the direction between terminals 107, 108, will generate a magnetic flux flowing through coil 402 in the positive or negative z direction and looping back around the outside of coil 402 in the negative or positive z direction. The relative (e.g., orthogonal) orientations of coils 101, 301, 402 has the effect of preventing (or minimizing) magnetic coupling between coils 101, 301, 402, and thereby preventing (or minimizing) interference between coils 101, 301, 402.

Coils 401, 402 are parallel and may be coupled magnetically, and substantially so. While the prevention (or minimization) of coupling and interference between coils (e.g., with coils 101, 301) is beneficial in some applications, the magnetic coupling of coils 401, 402 may be employed advantageously. The orientation of coils 401, 402 differs from coils 101, 301 in at least one significant way. Unlike coils 101, 301, the magnetic flux of coils 401, 402 flows in the positive or negative z direction through coils 401, 402 and loops back around the outside of coils 401, 402 in the opposite (e.g., negative or positive) z direction. The substrate between coils 401, 402 is perpendicular to the z direction. Eddy currents may be induced, perpendicular to a magnetic field, in closed loops within conductors. These eddy currents are induced by a changing (e.g., switching or alternating) magnetic field in the conductor(s). While the substrate may be of a semiconducting (rather than conducting) material, a semiconductor substrate offers less resistance to eddy currents than do the dielectric sections on sides 131, 132 of the substrate. The eddy currents induced in the substrate by inductors or coils 401, 402 (and the corresponding magnetic losses) reduce the quality factors or Q of these inductors. With the proper configuration, e.g., with an orientation of coils 401, 402 such that their currents generate opposing (rather than additive or reinforcing) magnetic fluxes, the magnetic fluxes of coils 401, 402 may cancel each other (at least partially) in the pertinent closed loops within the semiconductor substrate. The effect of any such cancellation may be a reduced eddy current and increased Q for coil 401 or 402.

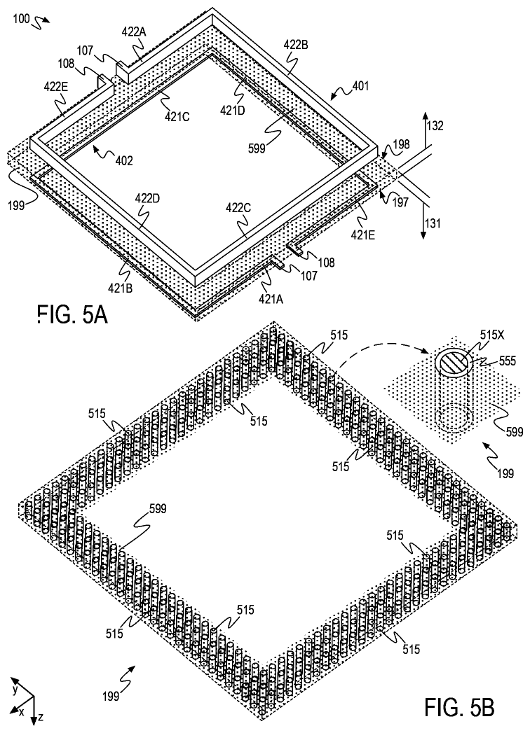

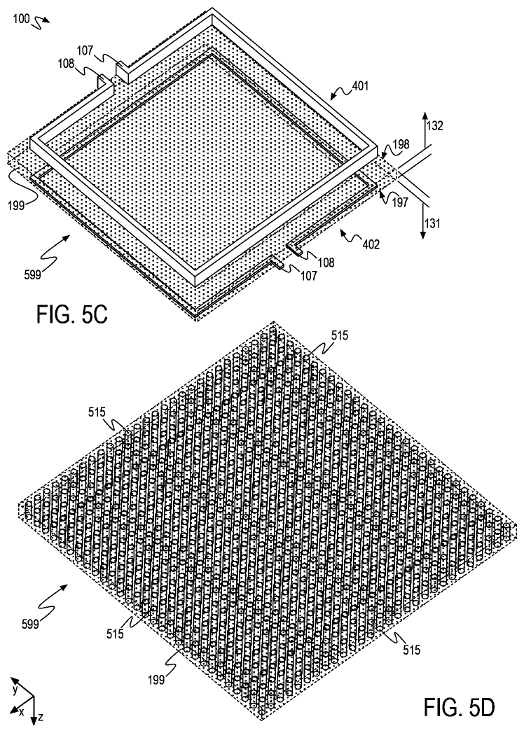

FIGS. 5A, 5B, 5C, and 5D illustrate isometric views of substrate 199 with an array of floating vias 515 deployed in a region 599 adjacent coils 401, 402, in accordance with some embodiments. The array of vias 515 may have the effect of a reduced eddy current and increased Q for coil 401 or 402. Vias 515 may be floating, e.g., not connected to current-bearing circuits, and need not be designed to carry current load. Coils 401, 402 are shown on opposite sides 131, 132 of substrate 199, but device 100 may include other, unshown coils 101, 301, 401, 402.

FIG. 5A illustrates device 100 and substrate 199 with region 599 shown adjacent and between coils 401, 402. In some embodiments, region 599 has a composition or structure different from other regions of substrate 199. Such a compositional or structural difference may have the effect of inhibiting or reducing the induction of eddy currents in and adjacent to region 599. Region 599 (in semiconducting substrate 199 and adjacent coils 401, 402) may be that area otherwise most susceptible to eddy currents.

Region 599 may be a large or small region (e.g., outer region) of substrate 199. In some embodiments, region 599 occupies an outer 25% of a cross-sectional width of substrate 199 (e.g., in the x or y directions). In some embodiments, substrate 199 includes one or more regions 599, localized to adjacent coils 401, 402, whether along an outer edge of substrate 199 or not. In some embodiments, region 599 and vias 515 occupy most of substrate 199.

FIG. 5B shows the same region 599 in the same substrate 199, but (e.g., for illustrative purposes) without showing coils 401, 402. An array of vias 515 are deployed throughout region 599 of substrate 199. Vias 515 may be similar to TSV 111, 112, as previously described, but may differ as necessary to reduce cost, improve performance, etc., of device 100. For example, as vias 515 need not carry current, the structures of vias 111, 112, 515 need not be optimized for the same parameters. However, vias 111, 112, 515 may maintain a standard structure, composition, etc., as is convenient.

While each via 515 includes conductive material, that material is insulated from substrate 199 and may be “floating” (e.g., isolated from, and having only high-impedance paths to, circuits and conductive components). Floating vias 515 may all have a similar structure, as illustrated by the magnified view of example floating via 515X. Vias 515 extend in the z direction through substrate 199 in region 599 (e.g., adjacent coils 401, 402). Extending through substrate 199, vias 515 may contact insulating material (e.g., of dielectric sections on sides 131, 132 of substrate 199) at top and bottom ends. Vias 515 are each encircled by a layer 555 of insulating (e.g., low-permittivity (“low-K”) dielectric) material. Layers 555 of dielectric material separate each via 515 from substrate 199 (and the semiconducting material of substrate 199). Floating vias 515 (and the insulating material of layers 555) break up semiconductive substrate 199, which may inhibit eddy currents.

Vias 515 may be organized in arrays to most efficiently inhibit eddy currents, e.g., to provide more tortuous paths through substrate 199. Vias 515 may have a uniform structure or various structures. The structure or structures of vias 515 may optimize one or more parameters, such as mechanical strength of substrate 199 or impedance to induced eddy currents. For example, a wider diameter of via 515 (with a constant thickness of layer 555) may better impede eddy currents. A narrower diameter of via 515, but with an increased thickness of layer 555, may have a similar effect on eddy currents while reducing cost.

Region 599 having vias 515 can be any of various shapes and/or sizes. For example, region 599 with vias 515 can be larger, occupying as much of substrate 199 as necessary. FIGS. 5C and 5D show a larger region 599 occupying the entirety of the same or a similar substrate 199 described at FIGS. 5A and 5B. Vias 515 are deployed in an array throughout region 599 and all of substrate 199. Other embodiments may employ other sizes and/or shapes of region 599, e.g., localized to certain components of device 100 (such as coils 401, 402, etc.).

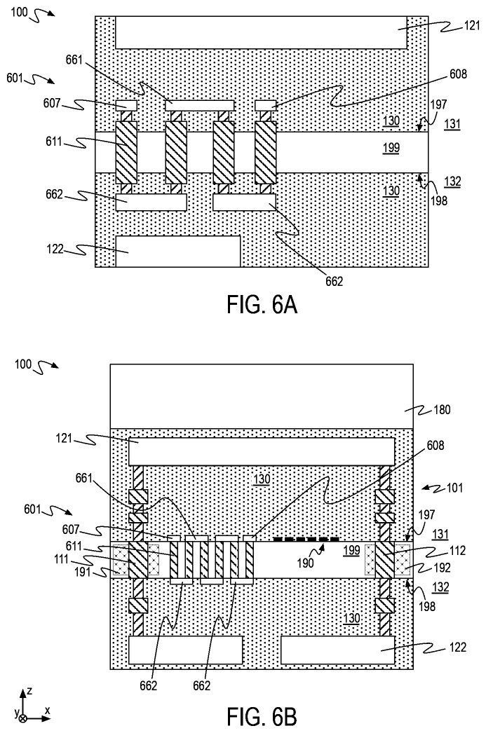

FIGS. 6A and 6B illustrate cross-sectional profile views of resistor 601 utilizing TSV 611 and resistors 661, 662 on both sides 131, 132 of substrate 199, in accordance with some embodiments. Resistor 601 includes resistors 661, 662 series connected by vias 611 between terminals 607, 608 of resistor 601. Resistor 601 may utilize TSV 611 to advantageously provide layout flexibility and increased resistance (as desired) in less area of substrate 199.

FIG. 6A shows resistor 601 spanning substrate 199. Resistor 601 includes one or more resistors 661 on side 131 of substrate 199, one or more resistors 662 on side 132 of substrate 199, and multiple vias 611 extending through substrate 199 in the z direction, between dielectric sections 130 on both sides 131, 132. Each of resistors 661 are coupled to one or more resistors 662 by vias 611. Resistors 661, vias 611, and resistors 662 are electrically coupled in series connection.

Resistors 661, 662 may be of any suitable structure and material(s), including structures and materials typical to the semiconductor manufacturing industry (e.g., thin-film resistors, polycrystalline semiconductor resistors, or implanted or diffused resistors in monocrystalline semiconductor material). Resistors 661, 662 may be on or over surfaces 197, 198 of substrate 199, e.g., within a coil and between wires 121, 122 and substrate 199.

Vias 611 may be the same as or similar to TSV 111, 112, as previously described, or vias 611 may be optimized for the application of coupling resistors 661, 662 on sides 131, 132 in series as part of an integrated resistor 601. For example, vias 611 may be thinner than TSV 111, 112, e.g., to increase a series resistance of TSV 611 and resistor 601. TSV 611 span between surfaces 197, 198 and dielectric sections 130 on sides 131, 132.

Resistor 601 may use less area by overlapping the areas used by resistors 661 on side 131 and by resistors 662 on side 132. Any series resistance of vias 611 may also be advantageously used in the total series resistance of resistor 601. The use of TSV 611 and both sides 131, 132 by resistor 601 provides an extra degree of freedom in routing resistor 601 between terminals 607, 608.

FIG. 6B illustrates resistor 601 within (e.g., enclosed by) coil 101 in device 100. Resistor 601 is between regions 191, 192 and adjacent one or more transistor structures 190 (e.g., in an array). One or more resistors 601 may be coupled to one or more of transistor structures 190 and/or coils 101, etc.

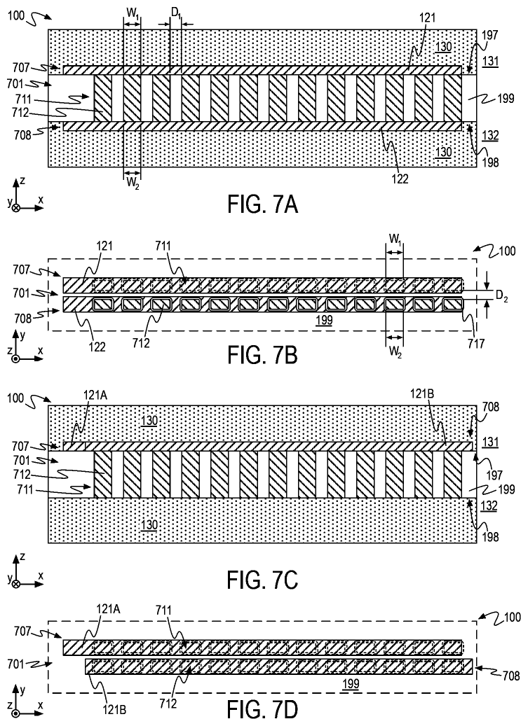

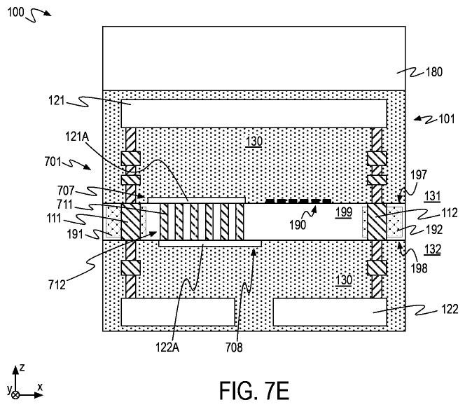

FIGS. 7A, 7B, 7C, 7D, and 7E illustrate cross-sectional profile and plan views of capacitor 701 utilizing TSV 711, 712 between sides 131, 132 of substrate 199, in accordance with some embodiments. Capacitor 701 employs vias 711, 712 as capacitor plates coupled to opposite terminals 707, 708. Capacitor 701 includes one or more vias 711 coupled to terminal 707 and one or more vias 712 coupled to terminal 708. Each of vias 711, 712 extend in the z direction through substrate 199 and between dielectric sections 130 on sides 131, 132. Each of vias 711, 712 extend between surfaces 197, 198 of substrate 199. Each of vias 711 are parallel and adjacent to corresponding vias 712.

FIG. 7A shows a profile view of capacitor 701 in device 100. In FIG. 7A, capacitor 701 includes terminal 707 on or coupled to wire 121 on side 131 of substrate 199, and on or over surface 197. Capacitor 701 includes terminal 708 on or coupled to wire 122 on side 132, and on or over surface 198. In the example of FIG. 7A, wires 121, 122 are on surfaces 197, 198, immediately adjacent substrate 199. Vias 712 are coupled to wire 122 and terminal 708. Vias 711, coupled to wire 121 and terminal 707, are behind (e.g., in the y direction) and obscured by vias 712.

Vias 711, 712 may be the same as or similar to TSV 111, 112, as previously described, or vias 711, 712 may be optimized for an application of capacitor 701, e.g., using z height of device 100 to provide a space-efficient capacitance. For example, vias 711, 712 may be wider (e.g., in the x direction in FIG. 7A) than TSV 111, 112, e.g., to increase a capacitance of capacitor 701 and between TSV 711, 712. In some embodiments, a width W1 of vias 711 is equal to a width W2 of vias 712, and widths W1, W2 (e.g., in the x direction) are greater than a distance D1 (e.g., in the x direction) between vias 711 and between vias 712. In some embodiments, distance D1 is less than or equal to twice width W1 or W2.

FIG. 7B illustrates an overhead view of capacitor 701 in device 100, for example, from above wire 121, and as described at FIG. 7A. In FIG. 7B, vias 711 are behind (e.g., in the z direction, under) wire 121, as indicated by their dashed borders. Vias 712 are over wire 122. Each of vias 711, 712 are encircled by a layer 717 of insulating (e.g., dielectric) material. Layers 717 of dielectric material separate each via 711, 712 from substrate 199. Layers 717 of dielectric material may be of the same dielectric material as in layers 555 of dielectric material encircling vias 515 (e.g., as described at FIG. 5B) or encircling, for example, TSV 111, 112. In some embodiments, layers 717 of dielectric material are of a high-K dielectric material, e.g., of a metal oxide (such as of hafnium, etc.) or of a nitrided native oxide (such as a silicon oxynitride). The deployment of a high-K material may advantageously provide a capacitor 701 having higher capacitance (for example, than capacitor 701 with a low-K dielectric material in layer 717). In some embodiments, a thickness of layer 717 is thicker than a thickness of layers 555 of dielectric material encircling vias 515 (e.g., as described at FIG. 5B) or encircling, for example, TSV 111, 112. Thicker layers 717 (e.g., replacing a same volume of semiconductor material of substrate 199) may have the effect of increased capacitance of capacitor 701.

As described at FIG. 7A, vias 711, 712 may be wider (e.g., in the x direction in FIG. 7A) than TSV 111, 112. In some embodiments, widths W1, W2 of vias 711, 712 (e.g., in the x direction) are greater than a distance D2 (e.g., in the y direction) between vias 711, 712. In some embodiments, distance D2 is less than or equal to twice width W1 or W2.

FIG. 7C shows a similar profile view of capacitor 701 as at FIG. 7A. Notably, in the example of FIG. 7C, terminals 707, 708 are both on side 131 and surface 197, on or coupled to wires 121. Vias 712 are coupled to wire 121B and terminal 708. Vias 711, coupled to wire 121A and terminal 707, are behind (e.g., in the y direction) and obscured by vias 712. Wire 121A is behind (e.g., in the y direction) and partially obscured by wire 121B. Terminals 707, 708 may be on either side 131, 132 of substrate 199, e.g., to facilitate electrical connections as is convenient for a certain circuit configuration.

FIG. 7D illustrates a similar overhead view of capacitor 701 as at FIG. 7C. Notably, in the example of FIG. 7D, terminals 707, 708 are both on or coupled to wires 121. Vias 711, 712 are both behind (e.g., under, in the z direction) wire 121, as indicated by their dashed borders.

FIG. 7E shows capacitor 701 within (e.g., enclosed by) coil 101 in device 100. Capacitor 701 is between regions 191, 192 and adjacent one or more transistor structures 190 (e.g., in an array). Terminal 707 is on or coupled to wire 121A on surface 197 and side 131, and terminal 708 is on or coupled to wire 122A on surface 198 and side 132. One or more capacitors 701 may be coupled to one or more of transistor structures 190 and/or coils 101, etc.

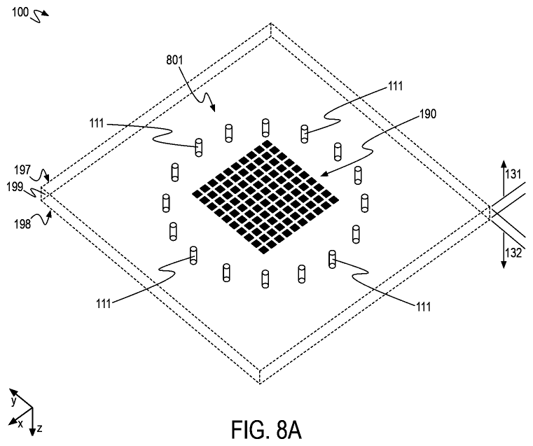

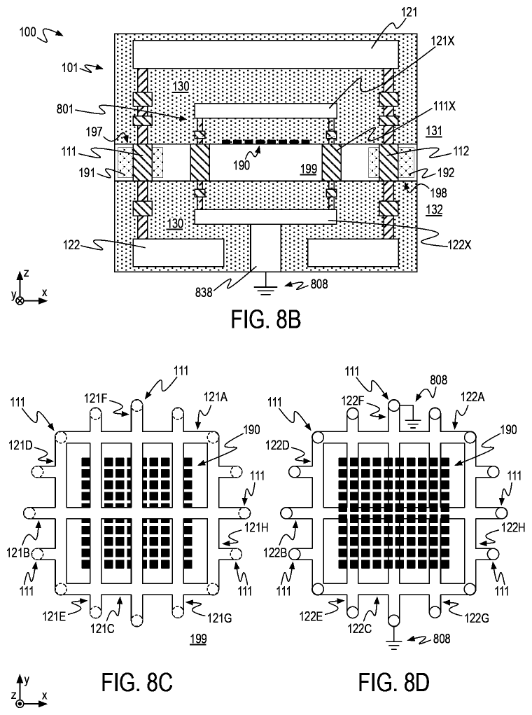

FIGS. 8A, 8B, 8C, and 8D illustrate isometric, cross-sectional profile, and plan views of an isolation or Faraday cage 801 in IC device 100, in accordance with some embodiments. Cage 801 includes vias 111 through substrate 199 and coupled to wires 121, 122 in dielectric sections 130 on both sides 131, 132 of substrate 199. Cage 801 may be an enclosure that shields components or devices within cage 801, such as transistor structures 190, from interfering fields (e.g., time-varying electromagnetic fields) external to cage 801.

FIG. 8A shows an isometric view of substrate 199 and a portion of cage 801. TSV 111 are part of cage 801. Vias 111 extend through substrate 199 between surfaces 197, 198 on sides 131, 132. An array of multiple transistor structures 190 are on upper surface 197 and side 131 of substrate 199. As part of cage 801, TSV 111 are coupled to wires (not shown, for illustrative clarity) over and under TSV 111 and transistor structures 190. The enclosure of cage 801 shields internal components, such as transistor structures 190, from external electromagnetic interference (EMI) or other, e.g., signals that may interfere with the operation of such components. Cage 801 may be a Faraday cage. A Faraday cage (or shield) may be an enclosure used to block electromagnetic fields.

FIG. 8B illustrates a cross-sectional profile view of shield enclosure or cage 801 in device 100. Cage 801 includes a group of vias 111 (e.g., via 111X). Each of vias 111 extends through substrate 199 and between dielectric sections 130. Cage 801 includes a group of wires 121, 122 (e.g., wires 121X, 122X) coupled to the group of vias 111. The group of wires 121, 122 includes one or more wires 121 in dielectric section 130 on side 131 and one or more wires 122 in dielectric section 130 on side 132. Device 100 includes a group of transistor structures 190 on side 131 of substrate 199. The group of transistor structures 190 is within cage 801. The group of transistor structures 190 is within a volume bounded by the groups of vias 111 and wires 121, 122. The groups of vias 111 and wires 121, 122 are coupled to a ground terminal 808 of device 100 by via 838 through dielectric section 130 on lower side 132 of substrate 199.

As shown in FIG. 8B, device 100 includes coil 101 with vias 111, 112 extending through substrate 199 and between dielectric sections 130 on sides 131, 132. Coil 101 also includes wires 121, 122 above and below cage 801 in dielectric sections 130. Wire 121 couples vias 111, 112.

Though device 100 is shown with only a single coil 101 in FIG. 8B, device 100 may include multiples coils 101, 301, 401, or 402, and cage 801 may be situated within one or more of the coils 101, 301, 401, or 402. For example, device 100 may include a coil 401 (or 402) with wires 122 (or 121) in dielectric section 130 on side 132 (or 131), as described at least at FIG. 4B.

Cage 801 may shield components, such as transistor structures 190, from electromagnetic fields external to cage 801 (including from any of coils 101, 301, 401, or 402). Any electric field external to cage 801 causes electric charges within vias 111 and wires 121, 122 of cage 801 to be distributed such that the charges cancel any effect of the field inside cage 801. Wires 121, 122 and vias 111 of cage 801 shield the interior of cage 801 from external electromagnetic radiation if wires 121, 122 and vias 111 are thick enough and any openings between wires 121, 122 and vias 111 are significantly smaller than the wavelength of the radiation. Higher frequency signals (e.g., with smaller wavelengths) may not be shielded by cage 801. Wires 121, 122 and vias 111 of cage 801 may be sufficiently thick and close together to shield, e.g., transistor structures 190, from any signals of interest (e.g., over pertinent frequencies). In some embodiments, wires 121 and/or vias 111 of cage 801 are deployed a nearly uniform distance (e.g., almost conformally) from shielded components (such as transistor structures 190), e.g., to minimize area occupied by cage 801 and to minimize the size of openings between wires 121, 122 and vias 111.

FIG. 8C shows an overhead plan view of cage 801 as shown in FIGS. 8A and 8B, for example, from below wire 121 in coil 101, but over wire 121X of cage 801. Wires 121 (e.g., wires 121A, 121B, 121C, 121D, 121E, 121F, 121G, 121H) are over the group of transistor structures 190 within the volume bounded by the groups of vias 111 and wires 121, 122. Wire 121B may be the wire 121X indicated in the cross-sectional profile view of FIG. 8B.

FIG. 8D illustrates a plan view of cage 801 as shown in FIGS. 8A-8C, for example, from below wire 121X in cage 801, but over transistor structures 190 on upper surface 197 of substrate 199. The group of transistor structures 190 are over wires 122 (e.g., wires 122A, 122B, 122C, 122D, 122E, 122F, 122G, 122H) of cage 801. Wire 122B may be the wire 122X indicated in the cross-sectional profile view of FIG. 8B.

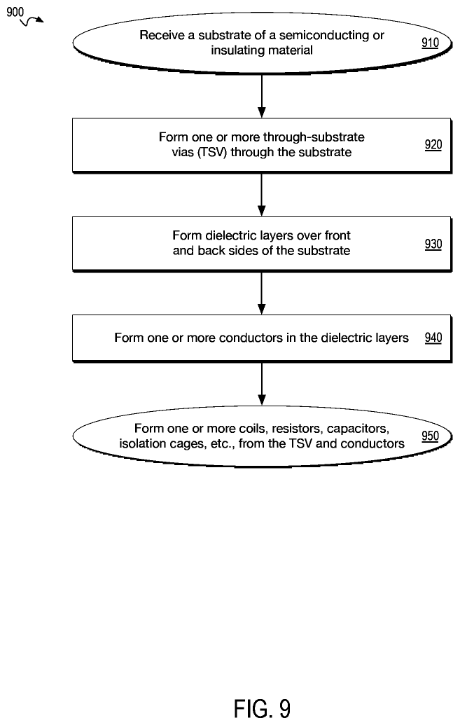

FIG. 9 is a flow chart of methods 900 for forming magnetic and/or electric structures in an IC device with front- and back-side interconnect structures, in accordance with some embodiments. Methods 900 include operations 910-950. Some operations shown in FIG. 9 may be optional. Additional operations may be included. FIG. 9 shows an example sequence, but the operations can be done in other orders as well, and some operations may be omitted. Some operations can also be performed multiple times before other operations are performed. For example, dielectric layers may be formed over the substrate. Some operations may be included within other operations so that the number of operations illustrated FIG. 9 is not a limitation of the methods 900.

Methods 900 begin with receiving a substrate at operation 910. The substrate may be a semiconductor substrate, for example, of monocrystalline silicon, a III-V semiconductor, silicon carbide, etc. (as substrate 199 is described at FIG. 1A). The substrate may be of a crystalline material, including an insulator. The substrate may initially (as received) have a standard wafer thickness or be very thin. The substrate may already include transistor structures and/or other devices.

Methods 900 continue with forming one or more TSV through the substrate at operation 920. The TSV may be formed at one or more stages of manufacture. For example, the TSV may be via-first, via-middle, or via-last TSV. In some embodiments, the TSV are formed through the substrate prior to the formation of components and circuits on the substrate. In some embodiments, the TSV are formed through the substrate after the formation of at least some components and circuits on the substrate, but prior to the formation of at least some interconnect structures on one or both sides of the substrate. In some embodiments, the TSV are formed through the substrate after the formation of at least interconnect structures on one or both sides of the substrate.

The via holes may be formed through the substrate by any suitable means, e.g., mechanically. In some embodiments, the TSV holes are formed by an etch, for example, a reactive-ion etch (RIE), such as a deep RIE (DRIE). In some embodiments, a TSV hole is formed by a laser drill. In some embodiments, the TSV are formed concurrently with vias through one or more dielectric layers over one or both sides of the substrate.

An insulating material may be formed (e.g., grown or deposited) over the inner (substrate) surface(s) of a TSV hole prior to forming one or more conductive materials in the hole. For example, in some embodiments, a TSV hole is formed through a silicon substrate, and a passivation layer or native oxide (e.g., silicon dioxide, SiO₂) is grown over the inner surface. In some embodiments, an insulating layer is conformally deposited.

Methods 900 continue by forming dielectric layers over the front and back sides of the substrate at operation 930. The dielectric layers may be formed by an any suitable means and of any suitable material or materials. The dielectric layers may include insulating material(s), e.g., low-K dielectrics, such as a silicon oxide, silicate glass, etc. The dielectric layers may be formed by, e.g., chemical vapor deposition (CVD). The dielectric layers may be of various materials (e.g., in separate layers), and different dielectric layers may be formed (e.g., deposited) by different means.

One or more dielectric layers may be formed before and after other operations. For example, one or more dielectric layers may be formed over one or both sides of the substrate with some layers formed after conductors are formed in and through a previous layer.

Methods 900 continue at operation 940 with forming one or more conductors (such as wires and/or vias) in the dielectric layers. Conductors may be formed by usual means, for example, damascene and dual-damascene, in and through the one or more dielectric layers. Openings (e.g., trenches and/or via holes) may be formed (e.g., etched) in the dielectric layers, and conductive material (e.g., one or more metals, such as copper) may be deposited in the openings. In some embodiments, a barrier or liner metal is deposited, e.g., in a thin layer, over a dielectric layer, and a bulk or fill metal is deposited over the liner metal. In some such embodiments, the barrier or liner metal acts as a seed layer for the growth of the bulk or fill metal.

Wires may be formed, e.g., in trenches, laterally through the dielectric layers, for example, to couple two vias. Vias may be formed vertically through the dielectric layers, for example, to couple a wire (perhaps to yet be formed) in an upper dielectric layer to a TSV or to a wire or via in a lower dielectric layer.

Methods 900 continue by forming one or more magnetic and/or electric structures from the TSV and conductors in the dielectric layers at operation 950. Forming these structures may include coupling TSV to wires or other vias, etc. In some embodiments, the structure(s) are formed by the forming or coupling of a wire to a TSV. For example, a coil may be formed by forming two TSV through a substrate (e.g., of silicon), multiple vias through dielectric (interconnect) sections on both sides of the substrate and coupling the TSV, and wires through both dielectric sections on both sides of the substrate coupling the vias. In some embodiments, a coil is formed by forming wires (e.g., in a single layer) through a dielectric section on a single side of the substrate. In some such embodiments, the coil may be coupled to one or more components or circuits on the opposite side of the substrate by one or more TSV.

In some embodiments, a resistor is formed by coupling constituent resistor segments both sides of the substrate with TSV. In some embodiments, the TSV and resistor segments may be coupled by forming the resistor segments over the TSV already through the substrate.

In some embodiments, a capacitor is formed by coupling one group of TSV to each other and by coupling a second group of TSV to each other, such that the first and second groups of TSV are adjacent and parallel plates. In some embodiments, the TSV may be coupled by forming a wire over each group of TSV already through the substrate.

In some embodiments, an isolation cage is formed by coupling a group of TSV to each other with wires on both sides of the substrate. The TSV may laterally bound a volume having components on the substrate that are to be shielded (e.g. isolated) from interference. The wires may vertically bound the volume to be shielded, and the coupled TSV and wires form a cage around the shielded volume. In at least some embodiments, the cage is coupled to a system (e.g., package or device) electrical ground, for example, through a power interconnect structure on a back side of the substrate.

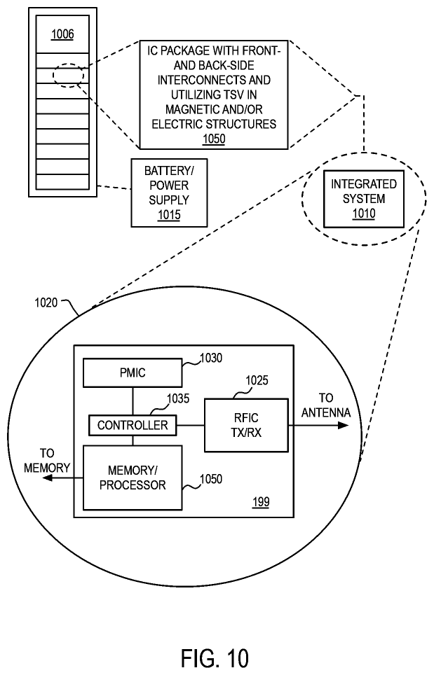

FIG. 10 illustrates a diagram of an example data server machine 1006 employing an IC device having front- and back-side interconnects and utilizing TSV in magnetic and/or electric structures, in accordance with some embodiments. Server machine 1006 may be any commercial server, for example, including any number of high-performance computing platforms disposed within a rack and networked together for electronic data processing, which in the exemplary embodiment includes one or more devices 1050 with front- and back-side interconnects and utilizing TSV in magnetic and/or electric structures.

Also as shown, server machine 1006 includes a battery and/or power supply 1015 to provide power to devices 1050, and to provide, in some embodiments, power delivery functions such as power regulation. Devices 1050 may be deployed as part of a package-level integrated system 1010. Integrated system 1010 is further illustrated in the expanded view 1020. In the exemplary embodiment, devices 1050 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 1050 is a microprocessor including a static RAM (SRAM) cache memory. As shown, device 1050 may be an IC device having front- and back-side interconnects and utilizing TSV in magnetic and/or electric structures, as discussed herein. Device 1050 may be further coupled to (e.g., communicatively coupled to) a board, an interposer, or a substrate 199 along with, one or more of a power management IC (PMIC) 1030, RF (wireless) IC (RFIC) 1025 including a wideband RF (wireless) transmitter and/or receiver (TX/RX) (e.g., including a digital baseband and an analog front end module further includes a power amplifier on a transmit path and a low noise amplifier on a receive path), and a controller 1035 thereof. In some embodiments, RFIC 1025, PMIC 1030, controller 1035, and device 1050 include front- and back-side interconnects and utilize TSV in magnetic and/or electric structures.

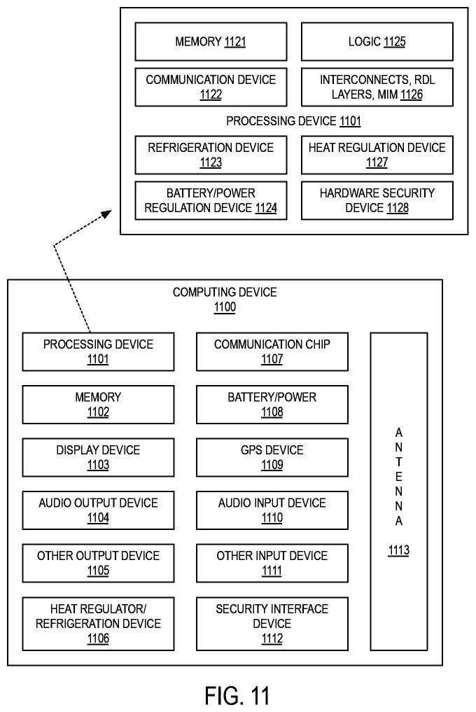

FIG. 11 is a block diagram of an example computing device 1100, in accordance with some embodiments. For example, one or more components of computing device 1100 may include any of the devices or structures discussed herein. A number of components are illustrated in FIG. 11 as being included in computing device 1100, but any one or more of these components may be omitted or duplicated, as suitable for the application. In some embodiments, some or all of the components included in computing device 1100 may be attached to one or more printed circuit boards (e.g., a motherboard). In some embodiments, various ones of these components may be fabricated onto a single system-on-a-chip (SoC) die. Additionally, in various embodiments, computing device 1100 may not include one or more of the components illustrated in FIG. 11, but computing device 1100 may include interface circuitry for coupling to the one or more components. For example, computing device 1100 may not include a display device 1103, but may include display device interface circuitry (e.g., a connector and driver circuitry) to which display device 1103 may be coupled. In another set of examples, computing device 1100 may not include an audio output device 1104, other output device 1105, global positioning system (GPS) device 1109, audio input device 1110, or other input device 1111, but may include audio output device interface circuitry, other output device interface circuitry, GPS device interface circuitry, audio input device interface circuitry, audio input device interface circuitry, to which audio output device 1104, other output device 1105, GPS device 1109, audio input device 1110, or other input device 1111 may be coupled.

Computing device 1100 may include a processing device 1101 (e.g., one or more processing devices). As used herein, the term “processing device” or “processor” indicates a device that processes electronic data from registers and/or memory to transform that electronic data into other electronic data that may be stored in registers and/or memory. Processing device 1101 may include a memory 1121, a communication device 1122, a refrigeration device 1123, a battery/power regulation device 1124, logic 1125, interconnects 1126 (i.e., optionally including redistribution layers (RDL) or metal-insulator-metal (MIM) devices), a heat regulation device 1127, and a hardware security device 1128.

Processing device 1101 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 1100 may include a memory 1102, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 1102 includes memory that shares a die with processing device 1101. This memory may be used as cache memory and may include embedded dynamic random-access memory (eDRAM) or spin transfer torque magnetic random-access memory (STT-MRAM).

Computing device 1100 may include a heat regulation/refrigeration device 1106. Heat regulation/refrigeration device 1106 may maintain processing device 1101 (and/or other components of computing device 1100) at a predetermined low temperature during operation.

In some embodiments, computing device 1100 may include a communication chip 1107 (e.g., one or more communication chips). For example, the communication chip 1107 may be configured for managing wireless communications for the transfer of data to and from computing device 1100. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 1107 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 1107 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 1107 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 1107 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 1107 may operate in accordance with other wireless protocols in other embodiments. Computing device 1100 may include an antenna 1113 to facilitate wireless communications and/or to receive other wireless communications (such as AM or FM radio transmissions).

In some embodiments, communication chip 1107 may manage wired communications, such as electrical, optical, or any other suitable communication protocols (e.g., the Ethernet). As noted above, communication chip 1107 may include multiple communication chips. For instance, a first communication chip 1107 may be dedicated to shorter-range wireless communications such as Wi-Fi or Bluetooth, and a second communication chip 1107 may be dedicated to longer-range wireless communications such as GPS, EDGE, GPRS, CDMA, WiMAX, LTE, EV-DO, or others. In some embodiments, a first communication chip 1107 may be dedicated to wireless communications, and a second communication chip 1107 may be dedicated to wired communications.

Computing device 1100 may include battery/power circuitry 1108. Battery/power circuitry 1108 may include one or more energy storage devices (e.g., batteries or capacitors) and/or circuitry for coupling components of computing device 1100 to an energy source separate from computing device 1100 (e.g., AC line power).

Computing device 1100 may include a display device 1103 (or corresponding interface circuitry, as discussed above). Display device 1103 may include any visual indicators, such as a heads-up display, a computer monitor, a projector, a touchscreen display, a liquid crystal display (LCD), a light-emitting diode display, or a flat panel display, for example.

Computing device 1100 may include an audio output device 1104 (or corresponding interface circuitry, as discussed above). Audio output device 1104 may include any device that generates an audible indicator, such as speakers, headsets, or earbuds, for example.

Computing device 1100 may include an audio input device 1110 (or corresponding interface circuitry, as discussed above). Audio input device 1110 may include any device that generates a signal representative of a sound, such as microphones, microphone arrays, or digital instruments (e.g., instruments having a musical instrument digital interface (MIDI) output).

Computing device 1100 may include a GPS device 1109 (or corresponding interface circuitry, as discussed above). GPS device 1109 may be in communication with a satellite-based system and may receive a location of computing device 1100, as known in the art.

Computing device 1100 may include other output device 1105 (or corresponding interface circuitry, as discussed above). Examples of the other output device 1105 may include an audio codec, a video codec, a printer, a wired or wireless transmitter for providing information to other devices, or an additional storage device.

Computing device 1100 may include other input device 1111 (or corresponding interface circuitry, as discussed above). Examples of the other input device 1111 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 1100 may include a security interface device 1112. Security interface device 1112 may include any device that provides security measures for computing device 1100 such as intrusion detection, biometric validation, security encode or decode, access list management, malware detection, or spyware detection.

Computing device 1100, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1-11. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a substrate of a semiconductor material between first and second dielectric sections, and a coil, including first and second vias extending through the substrate and between the first and second dielectric sections in a first direction substantially perpendicular to the substrate, and a first wire in the first dielectric section and extending in a second direction substantially parallel to the substrate, wherein the first wire couples the first and second vias.

In one or more second embodiments, further to the first embodiments, the first via is through a first region of the substrate, the second via is through a second region of the substrate, and a plurality of transistor structures is on the substrate and between the first and second regions and between the first and second dielectric sections.

In one or more third embodiments, further to the first or second embodiments, also including second and third wires in the second dielectric section and extending in the second direction, wherein the second via couples the first and second wires, and the first via couples the first and the third wires.

In one or more fourth embodiments, further to the first through third embodiments, also including a second wire and a third via, wherein the second wire extends in the second direction in the second dielectric section, the third via extends in the first direction through the substrate and between the first and second dielectric sections, the second via couples the first and second wires, and the second wire couples the second and third vias.

In one or more fifth embodiments, further to the first through fourth embodiments, also including a third wire in the first dielectric section, the third wire extending in the second direction and coupled to the third via.

In one or more sixth embodiments, further to the first through fifth embodiments, the coil is a first coil, and also including a second coil, the second coil including third and fourth vias extending through the substrate and between the first and second dielectric sections in the first direction, and a second wire in the first or second dielectric section and extending in a third direction substantially parallel to the substrate and substantially perpendicular to the first and second directions.

In one or more seventh embodiments, further to the first through sixth embodiments, the coil is a first coil, and also including a third coil in the first or second dielectric section, the third coil including fourth, fifth, and sixth wires, wherein the fourth, fifth, and sixth wires are substantially parallel to the substrate, the fourth wire is substantially parallel to the sixth wire, the fourth and sixth wires are substantially perpendicular to the fifth wire, and the fourth and sixth wires are coupled by the fifth wire.

In one or more eighth embodiments, further to the first through seventh embodiments, also including a plurality of fifth vias through the substrate and adjacent the third coil, wherein the fifth vias extend in the first direction, an individual one of the fifth vias is encircled by a layer of dielectric material, and the layer of dielectric material separates the individual one of the fifth vias from the substrate.

In one or more ninth embodiments, further to the first through eighth embodiments, also including a fourth coil in the first or second dielectric section, the fourth coil including seventh, eighth, and ninth wires, wherein the substrate is between the third and fourth coils, the seventh, eighth, and ninth wires are substantially parallel to the substrate, the seventh wire is substantially parallel to the ninth wire, the seventh and ninth wires are substantially perpendicular to the eighth wire, and the seventh and ninth wires are electrically coupled by the eighth wire.

In one or more tenth embodiments, further to the first through ninth embodiments, also including one or more first resistors on a first side of the substrate, one or more second resistors on a second side of the substrate, opposite the first side, and a plurality of third vias extending through the substrate and between the first and second dielectric sections in the first direction, wherein the one or more first resistors are coupled to the one or more second resistors by the third vias, and the one or more first resistors, the plurality of third vias, and the one or more second resistors are electrically coupled in series connection.

In one or more eleventh embodiments, further to the first through tenth embodiments, also including a capacitor, the capacitor including a plurality of third vias coupled to a first terminal, and a plurality of fourth vias coupled to a second terminal, wherein the third and fourth vias extend through the substrate and between the first and second dielectric sections in the first direction, and individual ones of the third vias are parallel and adjacent to corresponding ones of the fourth vias.

In one or more twelfth embodiments, further to the first through eleventh embodiments, the third vias have a first width approximately equal to a second width of the fourth vias, and corresponding and adjacent third and fourth vias are separated by a distance less than twice the first width.

In one or more thirteenth embodiments, an apparatus includes first and second dielectric sections and a substrate therebetween, wherein one or more transistor structures is on the substrate, and a coil in the first or second dielectric section, wherein the substrate is between the coil and the one or more transistor structures, the coil including a plurality of wires, the plurality including first, second, and third wires, wherein the first and third wires extend in a first direction substantially parallel to the substrate, the second wire extends in a second direction substantially parallel to the substrate and substantially perpendicular to the first direction, and the second wire couples the first and third wires.

In one or more fourteenth embodiments, further to the thirteenth embodiments, also including a plurality of vias through the substrate and adjacent the coil, wherein a layer of dielectric material is around an individual one of the vias, and the layer of dielectric material is between the individual one of the vias and the substrate.

In one or more fifteenth embodiments, further to the thirteenth or fourteenth embodiments, the coil is a first coil and the plurality of wires is a first plurality of wires, also including a second coil, wherein the substrate is between the first and second coils, the second coil includes a second plurality of wires, and the second plurality of wires includes fourth, fifth, and sixth wires, wherein the fourth and sixth wires extend in the first or second direction, and the fifth wire couples the fourth and sixth wires.

In one or more sixteenth embodiments, further to the thirteenth through fifteenth embodiments, also including a third coil, the third coil including first and second vias extending through the substrate and between the first and second dielectric sections in a third direction substantially perpendicular to the first and second directions, and a seventh wire in the first or second dielectric section and extending in the first or second direction, wherein the seventh wire couples the first and second vias.

In one or more seventeenth embodiments, further to the thirteenth through sixteenth embodiments, also including a fourth coil, the fourth coil including third and fourth vias extending through the substrate and between the first and second dielectric sections in the third direction, and an eighth wire in the first or second dielectric section and extending in the second or first direction, substantially perpendicular to the first or second direction of the seventh wire, wherein the eighth wire couples the third and fourth vias.

In one or more eighteenth embodiments, an apparatus includes a substrate between a first dielectric section on a first side of the substrate and a second dielectric section on a second side of the substrate, a plurality of vias, wherein individual ones of the vias extend through the substrate and between the first and second dielectric sections, a plurality of wires coupled to the plurality of vias, the plurality of wires including a first wire in the first dielectric section and a second wire in the second dielectric section, and a plurality of transistor structures on the first side of the substrate, wherein the plurality of transistor structures is within a volume bounded by the pluralities of vias and wires, and the pluralities of vias and wires are coupled to a ground terminal of the apparatus.

In one or more nineteenth embodiments, further to the eighteenth embodiments, also including a coil, wherein the vias are first vias, and the coil includes second and third vias extending through the substrate and between the first and second dielectric sections, and a third wire in the first or second dielectric section, wherein in the third wire couples the second and third vias.

In one or more twentieth embodiments, further to the eighteenth or nineteenth embodiments, also including a coil in the first or second dielectric section, the coil including third, fourth, and fifth wires, wherein the third, fourth, and fifth wires are substantially parallel to the substrate, the third wire is substantially parallel to the fifth wire, the third and fifth wires are substantially perpendicular to the fourth wire, and the third and fifth wires are coupled by the fourth wire.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a substrate of a semiconductor material between first and second dielectric sections; and
a coil, comprising:
first and second vias extending through the substrate and between the first and second dielectric sections in a first direction substantially perpendicular to the substrate; and
a first wire in the first dielectric section and extending in a second direction substantially parallel to the substrate, wherein the first wire couples the first and second vias.

2. The apparatus of claim 1, wherein the first via is through a first region of the substrate, the second via is through a second region of the substrate, and a plurality of transistor structures is on the substrate and between the first and second regions and between the first and second dielectric sections.

3. The apparatus of claim 1, further comprising second and third wires in the second dielectric section and extending in the second direction, wherein the second via couples the first and second wires, and the first via couples the first and the third wires.

4. The apparatus of claim 1, further comprising a second wire and a third via, wherein the second wire extends in the second direction in the second dielectric section, the third via extends in the first direction through the substrate and between the first and second dielectric sections, the second via couples the first and second wires, and the second wire couples the second and third vias.

5. The apparatus of claim 4, further comprising a third wire in the first dielectric section, the third wire extending in the second direction and coupled to the third via.

6. The apparatus of claim 1, wherein the coil is a first coil, and further comprising a second coil, the second coil comprising:
third and fourth vias extending through the substrate and between the first and second dielectric sections in the first direction; and
a second wire in the first or second dielectric section and extending in a third direction substantially parallel to the substrate and substantially perpendicular to the first and second directions.

7. The apparatus of claim 1, wherein the coil is a first coil, and further comprising a third coil in the first or second dielectric section, the third coil comprising fourth, fifth, and sixth wires, wherein:
the fourth, fifth, and sixth wires are substantially parallel to the substrate;
the fourth wire is substantially parallel to the sixth wire;
the fourth and sixth wires are substantially perpendicular to the fifth wire; and
the fourth and sixth wires are coupled by the fifth wire.

8. The apparatus of claim 7, further comprising a plurality of fifth vias through the substrate and adjacent the third coil, wherein the fifth vias extend in the first direction, an individual one of the fifth vias is encircled by a layer of dielectric material, and the layer of dielectric material separates the individual one of the fifth vias from the substrate.

9. The apparatus of claim 7, further comprising a fourth coil in the first or second dielectric section, the fourth coil comprising seventh, eighth, and ninth wires, wherein:
the substrate is between the third and fourth coils;
the seventh, eighth, and ninth wires are substantially parallel to the substrate;
the seventh wire is substantially parallel to the ninth wire;
the seventh and ninth wires are substantially perpendicular to the eighth wire; and
the seventh and ninth wires are electrically coupled by the eighth wire.

10. The apparatus of claim 1, further comprising:
one or more first resistors on a first side of the substrate;
one or more second resistors on a second side of the substrate, opposite the first side; and
a plurality of third vias extending through the substrate and between the first and second dielectric sections in the first direction, wherein:
the one or more first resistors are coupled to the one or more second resistors by the third vias; and
the one or more first resistors, the plurality of third vias, and the one or more second resistors are electrically coupled in series connection.

11. The apparatus of claim 1, further comprising a capacitor, the capacitor comprising:
a plurality of third vias coupled to a first terminal; and
a plurality of fourth vias coupled to a second terminal, wherein the third and fourth vias extend through the substrate and between the first and second dielectric sections in the first direction, and individual ones of the third vias are parallel and adjacent to corresponding ones of the fourth vias.

12. The apparatus of claim 11, wherein the third vias have a first width approximately equal to a second width of the fourth vias, and corresponding and adjacent third and fourth vias are separated by a distance less than twice the first width.

13. An apparatus, comprising:
first and second dielectric sections and a substrate therebetween, wherein one or more transistor structures is on the substrate; and
a coil in the first or second dielectric section, wherein the substrate is between the coil and the one or more transistor structures, the coil comprising a plurality of wires, the plurality comprising first, second, and third wires, wherein the first and third wires extend in a first direction substantially parallel to the substrate, the second wire extends in a second direction substantially parallel to the substrate and substantially perpendicular to the first direction, and the second wire couples the first and third wires.

14. The apparatus of claim 13, further comprising a plurality of vias through the substrate and adjacent the coil, wherein a layer of dielectric material is around an individual one of the vias, and the layer of dielectric material is between the individual one of the vias and the substrate.

15. The apparatus of claim 13, wherein the coil is a first coil and the plurality of wires is a first plurality of wires, further comprising a second coil, wherein:
the substrate is between the first and second coils;
the second coil comprises a second plurality of wires; and
the second plurality of wires comprises fourth, fifth, and sixth wires, wherein:
the fourth and sixth wires extend in the first or second direction; and
the fifth wire couples the fourth and sixth wires.

16. The apparatus of claim 15, further comprising a third coil, the third coil comprising:
first and second vias extending through the substrate and between the first and second dielectric sections in a third direction substantially perpendicular to the first and second directions; and
a seventh wire in the first or second dielectric section and extending in the first or second direction, wherein the seventh wire couples the first and second vias.

17. The apparatus of claim 16, further comprising a fourth coil, the fourth coil comprising:
third and fourth vias extending through the substrate and between the first and second dielectric sections in the third direction; and
an eighth wire in the first or second dielectric section and extending in the second or first direction, substantially perpendicular to the first or second direction of the seventh wire, wherein the eighth wire couples the third and fourth vias.

18. An apparatus, comprising:
a substrate between a first dielectric section on a first side of the substrate and a second dielectric section on a second side of the substrate;
a plurality of vias, wherein individual ones of the vias extend through the substrate and between the first and second dielectric sections;
a plurality of wires coupled to the plurality of vias, the plurality of wires comprising a first wire in the first dielectric section and a second wire in the second dielectric section; and
a plurality of transistor structures on the first side of the substrate, wherein the plurality of transistor structures is within a volume bounded by an enclosure comprising the pluralities of vias and wires, and the pluralities of vias and wires are coupled to a ground terminal of the apparatus.

19. The apparatus of claim 18, further comprising a coil, wherein the vias are first vias, and the coil comprises:
second and third vias extending through the substrate and between the first and second dielectric sections; and
a third wire in the first or second dielectric section, wherein in the third wire couples the second and third vias.

20. The apparatus of claim 18, further comprising a coil in the first or second dielectric section, the coil comprising third, fourth, and fifth wires, wherein:
the third, fourth, and fifth wires are substantially parallel to the substrate;
the third wire is substantially parallel to the fifth wire;
the third and fifth wires are substantially perpendicular to the fourth wire; and
the third and fifth wires are coupled by the fourth wire.
